(19) United States
(12) Patent Application Publication
(10) Pub. No.: US 2010/0183851 A1
(43) Pub. Date: Jul. 22, 2010

(54) Photoresist Image-forming Process Using Double Patterning

(76) Inventors: Yi Cao, Clinton, NJ (US); Muthiah Thiyagarajan, Bridgewater, NJ (US); SungEun Hong, Basking Ridge, NJ (US); DongKwan Lee, Bridgewater, NJ (US); Meng Li, Edison, NJ (US); David Mikrut, Staten Island, NY (US)

Correspondence Address: ALAN P. KASS;AZ ELECTRONIC MATERIALS USA CORP., 70 MEISTER AVENUE, SOMERVILLE, NJ, 08876, US

(21) Appl. No.: 12/356,568

(22) Filed: Jan. 21, 2009

(51) Int. Cl. B32B 5/00; G03F 7/20; G03F 7/004

(52) U.S. Cl. 428/195.1; 430/325; 430/270.1

(57) ABSTRACT

A process for forming a double photoresist pattern is disclosed.

### FIELD OF THE INVENTION

The present invention relates to a process for forming fine photoresist patterns on a device using double imagewise patterning as well as a process for shrinking the space dimensions between patterned photoresist features by increasing the dimensions of the photoresist pattern.

### DESCRIPTION

Photoresist compositions are used in microlithography processes for making miniaturized electronic components such as in the fabrication of computer chips and integrated circuits. Generally, in these processes, a thin coating of film of a photoresist composition is first applied to a substrate material, such as silicon wafers used for making integrated circuits. The coated substrate is then baked to evaporate any solvent in the photoresist composition and to fix the coating onto the substrate. The photoresist coated on the substrate is next subjected to an image-wise exposure to radiation.

The radiation exposure causes a chemical transformation in the exposed areas of the coated surface. Visible light, ultraviolet (UV) light, electron beam and X-ray radiant energy are radiation types commonly used today in microlithographic processes. After this image-wise exposure, the coated substrate is optionally baked, and then treated with a developer solution to dissolve and remove the radiation exposed positive photoresist.

Positive working photoresists when they are exposed image-wise to radiation have those areas of the photoresist composition exposed to the radiation become more soluble to the developer solution while those areas not exposed remain relatively insoluble to the developer solution. Thus, treatment of an exposed positive-working photoresist with the developer causes removal of the exposed areas of the coating and the formation of a positive image in the photoresist coating. Again, a desired portion of the underlying surface is uncovered.

Photoresist resolution is defined as the smallest feature which the photoresist composition can transfer from the photomask to the substrate with a high degree of image edge acuity after exposure and development. In many leading edge manufacturing applications today, photoresist resolution on the order of less than 100 nm is necessary. In addition, it is almost always desirable that the developed photoresist wall profiles be near vertical relative to the substrate. Such demarcations between developed and undeveloped areas of the photoresist coating translate into accurate pattern transfer of the mask image onto the substrate. This becomes even more critical as the push toward miniaturization reduces the critical dimensions on the devices.

Photoresists sensitive to short wavelengths, between about 100 nm and about 300 nm, are often used where subhalfmicron geometries are required. Particularly preferred are deep UV photoresists sensitive at below 200 nm, e.g. 193 nm and 157 nm, comprising non-aromatic polymers, a photoacid generator, optionally a dissolution inhibitor, base quencher and solvent.

High resolution, chemically amplified, deep ultraviolet (100-300 nm) positive tone photoresists are available for patterning images with less than quarter micron geometries.

The primary function of a photoresist is to accurately replicate the image intensity profile projected into it by the exposure tool. This becomes increasingly difficult as the distance between features on the mask shrinks since the image intensity contrast decreases and eventually vanishes when the distance falls below the diffraction limit of the exposure tool. In terms of device density, it is the feature pitch which is of primary importance since it relates to how close features can be packed. In order to form patterns in a photoresist film at pitches less than 0.5λ/NA (λ is the wavelength of the exposing radiation and NA is the numerical aperture of the lens for exposure), one technique that has been used is double patterning. Double patterning provides a method for increasing the density of photoresist patterns in a microelectronic device. Typically in double patterning a first photoresist pattern is defined on a substrate at pitches greater than 0.5λ/NA and then in another step a second photoresist pattern is defined at the same pitch as the first pattern between the first photoresist pattern. Both images are transferred simultaneous to the substrate with the resulting pitch that is half of the single exposures. Dual patterning approaches available today are based on forming two hard mask images via two pattern transfer processes. Double patterning allows for the photoresist features to be present in close proximity to each other, typically through pitch splitting.

In order to be able to coat a second photoresist over the patterned first photoresist, the first photoresist pattern is typically stabilized/hardened or frozen so that there is no intermixing with the second photoresist or deformation of the first photoresist pattern. Various types of double patterning methods are known which stabilize or freeze the first photoresist pattern prior to coating the second photoresist over the first photoresist pattern, such as thermally curing, UV curing, e-beam curing and ion implantation of the first photoresist pattern. Thermal curing can only be used for photoresists where the glass transition temperature of the photoresist polymer is higher than the stabilization temperature, and such a process is not useful for all photoresists. Stabilization of the first photoresist pattern prevents intermixing between the first photoresist pattern and the second photoresist layer, which allows for good lithographic images to be formed on the substrate. Thus there is a need for a process of stabilizing the first photoresist pattern which is useful for a wide range of photoresists.

The present invention relates to a double patterning process comprising a hardening treatment for the first photoresist pattern to increase its resistance to dissolution in the second photoresist solvent and to an aqueous alkaline developer, and also prevent intermixing with the second photoresist. The present invention also relates to a hardening composition and a coated substrate formed by the process herein.

### SUMMARY OF THE INVENTION

The present invention relates to a process for forming a photoresist pattern on a device, comprising; a) forming a layer of first photoresist on a substrate from a first photoresist composition; b) imagewise exposing the first photoresist; c) developing the first photoresist to form a first photoresist pattern; d) treating the first photoresist pattern with a hardening composition comprising a polymer, a hardening compound, optionally a surfactant, optionally a thermal acid generator, and a solvent selected from water, organic solvent, or a mixture thereof, thereby forming a hardened first photoresist pattern; e) forming a second photoresist layer on the region of the substrate including the hardened first photoresist pattern from a second photoresist composition; f) imagewise exposing the second photoresist; and, g) developing the imagewise exposed second photoresist to form a second photoresist pattern between the first photoresist pattern, thereby providing a double photoresist pattern. The treating step comprises the steps of (i) coating the first photoresist pattern with the hardening composition, (ii) soft baking the coated first photoresist pattern of (i), (iii) developing the baked coated first photoresist pattern of (ii) with water or an aqueous alkaline solution to remove the hardening composition, and (iv) optionally hard baking the developed first photoresist pattern of (iii).

With the foregoing, the present invention can increase the line density of a photoresist pattern. The process is particularly useful for coating over photoresists sensitive at 248 nm, 193 nm and 157 nm, as well as others as described herein. The process leads to improved pattern definition, higher resolution, low defects, and stable pattern formation of imaged photoresist.

### BRIEF DESCRIPTION OF THE DRAWINGS

FIG. 1 is schematic of one inventive process.

FIG. 2 is a schematic of the process between steps E and F in FIG. 1.

### DETAILED DESCRIPTION OF THE DRAWINGS

The present invention relates to a process for imaging fine patterns on a microelectronic device using double imagewise patterning of two photoresist layers. The process comprises patterning of a first photoresist layer followed by a second imagewise (using a mask or reticle) photoresist patterning step which forms a pattern interdigitated to the first pattern. Interdigitated refers to an alternating pattern of the second pattern placed between the first pattern. The double patterning step allows for an increase in pattern density as compared to a single patterning step. The inventive process comprises, a) forming a layer of first photoresist on a substrate from a first photoresist composition; b) imagewise exposing the first photoresist; c) developing the first photoresist to form a first photoresist pattern; d) treating the first photoresist pattern with a hardening composition comprising a polymer, a hardening compound, optionally a surfactant, optionally a thermal acid generator, and a solvent selected from water, organic solvent, or a mixture thereof, thereby forming a hardened first photoresist pattern; e) forming a second photoresist layer on the region of the substrate including the hardened first photoresist pattern from a second photoresist composition; f) imagewise exposing the second photoresist; and, g) developing the second photoresist pattern between the first photoresist pattern, thereby forming a double photoresist pattern. The treating step comprises the steps of (i) coating the first photoresist pattern with the hardening composition, (ii) soft baking the coated first photoresist pattern of (i), (iii) developing the baked coated first photoresist pattern of (ii) with water or an aqueous alkaline solution to remove the hardening composition, and (iv) optionally hard baking the developed first photoresist pattern of (iii).

The first layer of photoresist is imaged on a substrate using known techniques of forming a layer of a photoresist from a photoresist composition. The photoresist comprises a polymer, photoacid generator a solvent, and may further comprise additives such as basic qenchers, surfactants, dyes and crosslinkers. An edge bead remover may be applied after the coating steps to clean the edges of the substrate using processes well known in the art. The photoresist layer is softbaked to remove the photoresist solvent. The photoresist layer is then imagewise exposed through a mask or reticle, optionally post exposure baked, and then developed using an aqueous alkaline developer. After the coating process, the photoresist can be imagewise exposed using any imaging radiation, such as those ranging from 13 nm to 450 nm. Typical radiation sources are 13.5 nm (also known as EUV), 157 nm, 193 nm, 248 nm, 365 nm and 436 nm. The exposure may be done using typical dry exposure or may be done using immersion lithography. The exposed photoresist is then developed in an aqueous developer to form the photoresist pattern. The developer is preferably an aqueous alkaline solution comprising, for example, tetramethyl ammonium hydroxide. An optional heating step can be incorporated into the process prior to development and after exposure. The exact conditions of coating, baking, imaging and developing are determined by the photoresist used.

The substrates over which the photoresist coating is formed can be any of those typically used in the semiconductor industry. Suitable substrates include, without limitation, silicon, silicon substrate coated with a metal surface, copper coated silicon wafer, copper, aluminum, polymeric resins, silicon dioxide, metals, doped silicon dioxide, silicon nitride, tantalum, polysilicon, ceramics, aluminum/copper mixtures; gallium arsenide and other such Group III/N compounds. The substrate may comprise any number of layers made from the materials described above. These substrates may further have a single or multiple coating of antireflective coatings, hard masks, and/or underlayer coatings prior to the coating of the photoresist layer. The coatings may be inorganic, organic or mixture of these. The coatings may be siloxane or silicone on top of a high carbon content antireflective coating. Any types of antireflective coatings are known in the art may be used.

The present process is particularly suited to deep ultraviolet exposure. Typically chemically amplified photoresists are used. They may be negative or positive. To date, there are several major deep ultraviolet (UV) exposure technologies that have provided significant advancement in miniaturization, and these are radiation of 248 nm, 193 nm, 157 and 13.5 nm. Photoresists for 248 nm have typically been based on substituted polyhydroxystyrene and its copolymers/onium salts, such as those described in U.S. Pat. No. 4,491,628 and U.S. Pat. No. 5,350,660. On the other hand, photoresists for exposure below 200 nm require non-aromatic polymers since aromatics are opaque at this wavelength. U.S. Pat. No. 5,843,624 and U.S. Pat. No. 6,866,984 disclose photoresists useful for 193 nm exposure. Generally, polymers containing alicyclic hydrocarbons are used for photoresists for exposure below 200 nm. Alicyclic hydrocarbons are incorporated into the polymer for many reasons, primarily since they have relatively high carbon to hydrogen ratios which improve etch resistance, they also provide transparency at low wavelengths and they have relatively high glass transition temperatures. U.S. Pat. No. 5,843,624 discloses polymers for photoresist that are obtained by free radical polymerization of maleic anhydride and unsaturated cyclic monomers. Any of the known types of 193 nm photoresists may be used, such as those described in U.S. Pat. No. 6,447,980 and U.S. Pat. No. 6,723,488, and incorporated herein by reference.

Two basic classes of photoresists sensitive at 157 nm, and based on fluorinated polymers with pendant fluoroalcohol groups, are known to be substantially transparent at that wavelength. One class of 157 nm fluoroalcohol photoresists is derived from polymers containing groups such as fluorinated-norbornenes, and are homopolymerized or copolymerized with other transparent monomers such as tetrafluoroethylene (U.S. Pat. No. 6,790,587, and U.S. Pat. No. 6,849,377) using either metal catalyzed or radical polymerization. Generally, these materials give higher absorbencies but have good plasma etch resistance due to their high alicyclic content. More recently, a class of 157 nm fluoroalcohol polymers was described in which the polymer backbone is derived from the cyclopolymerization of an asymmetrical diene such as 1,1,2,3,3-pentafluoro-4-trifluoromethyl-4-hydroxy-1,6-heptadiene (Shun-ichi Kodama et al Advances in Resist Technology and Processing XIX, Proceedings of SPIE Vol. 4690 p76 2002; U.S. Pat. No. 6,818,258) or copolymerization of a fluorodiene with an olefin (U.S. Pat. No. 6,916,590). These materials give acceptable absorbance at 157 nm, but due to their lower alicyclic content as compared to the fluoro-norbornene polymer, have lower plasma etch resistance. These two classes of polymers can often be blended to provide a balance between the high etch resistance of the first polymer type and the high transparency at 157 nm of the second polymer type. Photoresists that absorb extreme ultraviolet radiation (EUV) of 13.5 nm are also useful and are known in the art. Photoresists sensitive to 365 nm and 436 nm may also be used. At the present time 193 nm photoresists are preferred.

The solid components of the photoresist composition are mixed with a solvent or mixtures of solvents that dissolve the solid components of the photoresist. Suitable solvents for the photoresist may include, for example, a glycol ether derivative such as ethyl cellosolve, methyl cellosolve, propylene glycol monomethyl ether, diethylene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate; carboxylates such as ethyl acetate, n-butyl acetate and amyl acetate; carboxylates of di-basic acids such as diethyloxylate and diethylmalonate; dicarboxylates of glycols such as ethylene glycol diacetate and propylene glycol diacetate; and hydroxy carboxylates such as methyl lactate, ethyl lactate, ethyl glycolate, and ethyl-3-hydroxy propionate; a ketone ester such as methyl pyruvate or ethyl pyruvate; an alkoxycarboxylic acid ester such as methyl3-methoxypropionate, ethyl3-ethoxypropionate, ethyl2-hydroxy-2-methylpropionate, or methylethoxypropionate; a ketone derivative such as methyl ethyl ketone, acetyl acetone, cyclopentanone, cyclohexanone or 2-heptanone; a ketone ether derivative such as diacetone alcohol methyl ether; a ketone alcohol derivative such as acetol or diacetone alcohol; a ketal or acetal like 1,3dioxalne and diethoxypropane; lactones such as butyrolactone; an amide derivative such as dimethylacetamide or dimethylformamide, anisole, and mixtures thereof. Typical solvents for photoresist, used as mixtures or alone, that can be used, without limitation, are propylene glycol monomethyl ether acetate (PGMEA), propylene glycol monomethyl ether (PGME), and ethyl lactate (EL), 2-heptanone, cyclopentanone, cyclohexanone, and gamma butyrolactone, but PGME, PGMEA and EL or mixtures thereof are preferred. Solvents with a lower degree of toxicity, good coating and solubility properties are generally preferred.

In one embodiment of the process a photoresist sensitive to 193 nm is used. The photoresist comprises a polymer, a photoacid generator, and a solvent. The polymer is an (meth)acrylate polymer which is insoluble in an aqueous alkaline developer. Such polymers may comprise units derived from the polymerization of monomers such as alicyclic(meth)acrylates, mevalonic lactone methacrylate, 2-methyl-2-adamantyl methacrylate, 2-adamantyl methacrylate (AdMA), 2-methyl-2-adamantyl acrylate (MAdA), 2-ethyl-2-adamantyl methacrylate (EAdMA), 3,5-dimethyl-7-hydroxy adamantyl methacrylate (DMHAdMA), isoadamantyl methacrylate, hydroxy-1-methacryloxyadamatane (HAdMA; for example, hydroxy at the 3-position), hydroxy-1-adamantyl acrylate (HADA; for example, hydroxy at the 3-position), ethylcyclopentylacrylate (ECPA), ethylcyclopentylmethacrylate (ECPMA), tricyclo[5,2,1,0^{2,6}]deca-8-yl methacrylate (TCDMA), 3,5-dihydroxy-1-methacryloxyadamantane (DHAdMA), β-methacryloxy-γ-butyrolactone, α- or β-gamma-butyrolactone methacrylate (either α- or β-GBLMA), 5-methacryloyloxy-2,6-norbornanecarbolactone (MNBL), 5-acryloyloxy-2,6-norbornanecarbolactone (ANBL),isobutyl methacrylate (IBMA), α-gamma-butyrolactone acrylate (α-GBLA), spirolactone(meth)acrylate, oxytricyclodecane(meth)acrylate, adamantane lactone(meth)acrylate, and α-methacryloxy-γ-butyrolactone, among others. Examples of polymers formed with these monomers include poly(2-methyl-2-adamantyl methacrylate-co-2-ethyl-2-adamantyl methacrylate-co-3-hydroxy-1-methacryloxyadamantane-co-α-gamma-butyrolactone methacrylate); poly(2-ethyl-2-adamantyl methacrylate-co-3-hydroxy-1-methacryloxyadamantane-co-β-gamma-butyrolactone methacrylate); poly(2-methyl-2-adamantyl methacrylate-co-3-hydroxy-1-methacryloxyadamantane-co-β-gamma-butyrolactone methacrylate); poly(t-butyl norbornene carboxylate-co-maleic anhydride-co-2-methyl-2-adamantyl methacrylate-co-β-gamma-butyrolactone methacrylate-co-methacryloyloxy norbornene methacrylate); poly(2-methyl-2-adamantyl methacrylate-co-3-hydroxy-1-methacryloxyadamantane-co-β-gamma-butyrolactone methacrylate-co-tricyclo[5,2,1,0^{2,6}]deca-8-yl methacrylate); poly(2-ethyl-2-adamantyl methacrylate-co-3-hydroxy-1-adamantyl acrylate-co-β-gamma-butyrolactone methacrylate); poly(2-ethyl-2-adamantyl methacrylate-co-3-hydroxy-1-adamantyl acrylate-co-α-gamma-butyrolactone methacrylate-co-tricyclo[5,2,1,0^{2,6}]deca-8-yl methacrylate); poly(2-methyl-2-adamantyl methacrylate-co-3,5-dihydroxy-1-methacryloxyadamantane-co-β-gamma-butyrolactone methacrylate); poly(2-methyl-2-adamantyl methacrylate-co-3,5-dimethyl-7-hydroxy adamantyl methacrylate-co-α-gamma-butyrolactone methacrylate); poly(2-methyl-2-adamantyl acrylate-co-3-hydroxy-1-methacryloxyadamantane-co-α-gamma-butyrolactone methacrylate); poly(2-methyl-2-adamantyl methacrylate-co-3-hydroxy-1-methacryloxyadamantane-co-β-gamma-butyrolactone methacrylate-co-tricyclo[5,2,1,0^{2,6}]deca-8-yl methacrylate); poly(2-methyl-2-adamantyl methacrylate-co-β-gamma-butyrolactone methacrylate-co-3-hydroxy-1-methacryloxyadamantane-co-ethylcyclopentylacrylate); poly(2-methyl-2-adamantyl methacrylate-co-3-hydroxy-1-adamantyl acrylate-co-α-gamma-butyrolactone methacrylate); poly(2-methyl-2-adamantyl methacrylate-co-3-hydroxy-1-methacryloxyadamantane-co-α-gamma-butyrolactone methacrylate-co-2-ethyl-2-adamantyl methacrylate); poly(2-methyl-2-adamantyl methacrylate-co-3-hydroxy-1-methacryloxyadamantane-co-β-gamma-butyrolactone methacrylate-co-tricyclo[5,2,1,0^{2,6}]deca-8-yl methacrylate); poly(2-methyl-2-adamantyl methacrylate-co-2-ethyl-2-adamantyl methacrylate-co-β-gamma-butyrolactone methacrylate-co-3-hydroxy-1-methacryloxyadamantane); poly(2-methyl-2-adamantyl methacrylate-co-2-ethyl-2-adamantyl methacrylate-co-α-gamma-butyrolactone methacrylate-co-3-hydroxy-1-methacryloxyadamantane); poly(2-methyl-2-adamantyl methacrylate-co-methacryloyloxy norbornene methacrylate-co-β-gamma-butyrolactone methacrylate); poly(ethylcyclopentylmethacrylate-co-2-ethyl-2-adamantyl methacrylate-co-α-gamma-butyrolactone acrylate); poly(2-ethyl-2-adamantyl methacrylate-co-3-hydroxy-1-adamantyl acrylate-co-isobutyl-methacrylate-co-α-gamma-butyrolactone acrylate); poly(2-methyl-2-adamantyl methacrylate-co-β-gamma-butyrolactone methacrylate-co-3-hydroxy-1-adamantyl acrylate-co-tricyclo[5,2,1,02,6]deca-8-yl methacrylate); poly(2-ethyl-2-adamantyl methacrylate-co-3-hydroxy-1-adamantyl acrylate-co-α-gamma-butyrolactone acrylate); poly(2-methyl-2-adamantyl methacrylate-co-β gamma-butyrolactone methacrylate-co-2-adamantyl methacrylate-co-3-hydroxy-1-methacryloxyadamatane); poly(2-methyl-2-adamantyl methacrylate-co-methacryloyloxy norbornene methacrylate-co-β-gamma-butyrolactone methacrylate-co-2-adamantyl methacrylate-co-3-hydroxy-1-methacryloxyadamatane); poly(2-methyl-2-adamantyl methacrylate-co-methacryloyloxy norbornene methacrylate-co-tricyclo[5,2,1,02,6]deca-8-yl methacrylate-co-3-hydroxy-1-methacryloxyadamatane-co-α-gamma-butyrolactone methacrylate); poly(2-ethyl-2-adamantyl methacrylate-co-3-hydroxy-1-adamantyl acrylate-co-tricyclo[5,2,1,02,6]deca-8-yl methacrylate-co-α-gamma-butyrolactone methacrylate); poly(2-ethyl-2-adamantyl methacrylate-co-3-hydroxy-1-adamantyl acrylate-co-α-gamma-butyrolactone acrylate); poly(2-methyl-2-adamantyl methacrylate-co-3-hydroxy-1-methacryloxyadamatane-co-α-gamma-butyrolactone methacrylate-co-2-ethyl-2-adamantyl-co-methacrylate); poly(2-ethyl-2-adamantyl methacrylate-co-3-hydroxy-1-adamantyl acrylate-co-α-gamma-butyrolactone methacrylate-co-tricyclo[5,2,1,0^{2,6}]deca-8-yl methacrylate); poly(2-ethyl-2-adamantyl methacrylate-co-3-hydroxy-1-adamantyl acrylate-co-α-gamma-butyrolactone methacrylate); poly(2-methyl-2-adamantyl methacrylate-co-3-hydroxy-1-adamantyl acrylate-co-5-acryloyloxy-2,6-norbornanecarbolactone); poly(2-ethyl-2-adamantyl methacrylate-co-3-hydroxy-1-adamantyl acrylate-co-α-gamma-butyrolactone methacrylate-co-α-gamma-butyrolactone acrylate); poly(2-ethyl-2-adamantyl methacrylate-co-3-hydroxy-1-adamantyl acrylate-co-α-gamma-butyrolactone methacrylate-co-2-adamantyl methacrylate); and poly(2-ethyl-2-adamantyl methacrylate-co-3-hydroxy-1-adamantyl acrylate-co-α-gamma-butyrolactone acrylate-co-tricyclo[5,2,1,02,6]deca-8-yl methacrylate).

The photoresist may further comprise additives such as basic qenchers, surfactants, dyes, crosslinkers, etc. Useful photoresists are further exemplified and incorporated by reference in U.S. application Ser. No. 11/834,490 and US publication number US 2007/0015084.

After the formation of the first photoresist pattern, the pattern is treated with a hardening composition to harden the photoresist so that the pattern becomes insoluble in the solvent of the second photoresist composition. In cases where the photoresist polymer has a glass transition temperature (Tg) lower than the hardening temperature of the photoresist alone, a hardening composition treatment is very useful, since lower temperatures than the Tg of the photoresist polymer can be used to harden the photoresist pattern.

In the present invention the hardening is done with a hardening composition comprising a polymer, a hardening compound, optionally a surfactant, optionally a thermal acid generator, and a solvent selected from water, organic solvent, or a mixture thereof. The hardening composition can also optionally contain a thermal acid generator. The hardening composition is coated over the first photoresist pattern, either completely (‘planarized’) or conformally. The hardening composition which is coated over first photoresist pattern is then soft baked, developed with water or an aqueous alkaline solution, and the first photoresist pattern is then optionally hard baked, thereby forming a hardened first photoresist pattern. Although not being bound by the theory, it is believed that the hardening compound diffuses through the first photoresist pattern and in the presence of heat reacts with the photoresist, thereby forming a hardened or frozen pattern. The pattern becomes insoluble in the solvent of the second photoresist composition.

The hardening treatment may be done on a hot plate with a chamber or an enclosed oven. The extent of hardening can be determined by soaking the hardened photoresist in the test solvent to measure the loss of the film thickness of the treated photoresist. Minimal film thickness loss is desirable, where the film thickness loss of the treated photoresist in the solvent of the second photoresist is less than 10 nm, preferably less than 8 nm and more preferably less than 5 nm. Insufficient hardening will dissolve the first photoresist. Specifically, the solvent may be selected from the solvent(s) of the photoresist described herein as an example.

Examples of the polymer in the hardening composition include a water soluble or essentially water soluble homopolymer or copolymer containing a lactam group. The polymer when referred to as water soluble is meant to encompass where the polymer is essentially water soluble. The composition comprises water but may include other water miscible solvent or solvents which further enhance the solubility of the polymer or other additives in the composition. The polymer may contain other functional groups which make the polymer water soluble, such as pyrrolidone, imidizole, C₁-C₆ alkyl amine, C₁-C₆ alkyl alcohol, carboxylic acid and amide. Other types of comonomeric units may also be present in the polymers.

The water soluble polymer of the hardening composition may comprise at least one unit of structure (1) derived from a vinyl monomer,

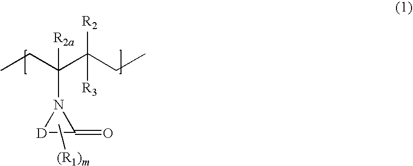

where R₁ is independently selected from hydrogen, C₁-C₄ alkyl, C₁-C₆ alkyl alcohol, hydroxy (OH), amine (NH₂), carboxylic acid, and amide (CONH₂), R₂, R₂ₐ, and R₃ are independently selected from hydrogen, C₁-C₆ alkyl, m=1-6, and n=1-7. Alkyl generally refers to linear and branched alkyls, and cyclic alkyls.

The polymer comprising structure (1) may be synthesized from any suitable vinyl monomers containing the lactam group. Specific examples of the monomers which are used to derive the unit of structure (1) are N-vinyllactams, more specifically, N-vinyl-2 piperidone, N-vinyl-4-methyl-2-piperidone, N-vinyl-4-ethyl-2-piperidone, N-vinyl-4-propyl-2-piperidone, N-vinyl-2-caprolactam, N-vinyl-4-methyl-2-caprolactam, N-vinyl-4-ethyl-2-caprolactam, N-vinyl-4-propyl-2-caprolactam, N-vinyl-4-butyl-2-caprolactam, N-vinyl-6-methyl-2-caprolactam, N-vinyl-6-ethyl-2-caprolactam, N-vinyl-6-propyl-2-caprolactam, N-vinyl-6-butyl-2-caprolactam, and their equivalents. More than one type of vinyllactam may be used in the synthesis of the polymer. The N-vinyl lactams may be copolymerized with other vinyl monomers, such as exemplified without limitation by N-vinyl pyrrolidone, acrylic acid, vinyl alcohol, methacrylic acid, N-vinylimidizole, acrylamide, allylamine, vinyl triazines, 2-vinyl-4,6-diamino-1,3,5-triazine, diallylamine, vinylamine; a cationic monomer such as dimethylaminoethyl acrylate, dimethylaminoethyl methacrylate, dimethylaminopropylmethacrylate; N-acryloylmorpholine, piperidinyl methacrylate; and bifunctional monomers such as ethyleneglycoldiacrylate, and ethyleneglycoldimethacrylate.

Other types of polymers containing the lactam group may be also be used. One example is cellulosic polymers. Cellulosic derivatives may be reacted with a compound containing a cyclic lactam group to give the polymer comprising a unit of structure (1). Examples of polymers that can react are hydroxypropylmethyl cellulose phthalate, hydroxypropylmethylcellulose acetate phthalate, hydroxypropylmethylcellulose acetate succinate and hydroxyethyl cellulose. Other types of water soluble polymers comprising the lactam group may also be used, such as alkyleneglycol polymers reacted with a compound containing a cyclic lactam group, urea polymers reacted with a compound containing a cyclic lactam group, melamine polymers reacted with a compound containing a cyclic lactam group, epoxy polymers reacted with a compound containing a cyclic lactam group, and amine polymers reacted with a compound containing a cyclic lactam group.

In one embodiment of the water soluble polymer, the polymer is polymerized from a mixture of N-vinyl-2-caprolactam, N-vinyl pyrrolidone and N-vinylimidizole. In another embodiment, the polymer is polymerized from a mixture of N-vinyl-2-caprolactam and N-vinyl pyrrolidone. In another embodiment the copolymers containing the lactam group are exemplified by poly(N-vinyl caprolactam-co-vinyl amine), poly(N-vinyl caprolactam-co-allyl amine), poly(N-vinyl caprolactam-co-diallyl amine), poly(N-vinyl caprolactam-co-acryloyl morpholine), poly(N-vinyl caprolactam-co-2-dimethylaminoethyl methacrylate), poly(N-vinyl caprolactam-co-piperidinyl methacrylate), poly(N-vinyl caprolactam-co-N-methyl N-vinylacetamide) and poly(N-vinyl caprolactam-co-dimethylaminopropyl methacrylamide).

The polymer comprising the lactam group in one embodiment is free of any aromatic moiety or absorbing chromophore. The polymer or the composition does not absorb the radiation used to image the photoresist which is coated beneath the shrink layer. The composition may be free of a photoacid generator such that the composition is not photoimageable.

Another water soluble polymer or essentially a water soluble polymer is one comprising at least one alkylamino group, where the monomeric unit comprising the alkylamino group has a structure (2),

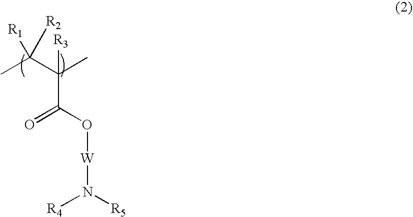

where, R₁ to R₅ are independently selected from hydrogen and C₁ to C₆ alkyl, and W is C₁ to C₆ alkylene. W is free of a carbonyl (C═O) group. W may be a branched or linear C₁ to C₆ alkylene. In one embodiment W may be selected from ethylene, propylene and butylene. In another embodiment R₄ and R₅ may be independently selected from methyl, ethyl, propyl and butyl. In yet another embodiment of the monomeric unit (2) in the polymer, R₁ and R₂ are hydrogen, R₃ is hydrogen or methyl, W is ethyl or propyl, and R₄ and R₅ may be selected from methyl, ethyl, propyl and butyl. Examples of monomers that may be used to form the monomeric unit of structure (2) are dimethylaminoethyl acrylate, dimethylaminoethyl methacrylate and dimethylaminopropylmethacrylate.

The polymer may be a homopolymer of the monomeric unit of structure (2). The polymer may also comprise at least one monomeric unit of structure (2) and at least one other comonomeric unit. The comonomeric unit may be a vinyl monomer. In one embodiment of the polymer in the novel composition, the polymer may comprise a unit of structure (2) and at least one unit of structure (3),

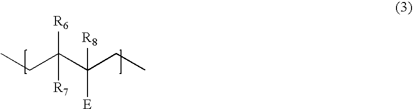

where E is R₅₀ or

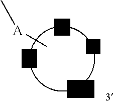

where R₆ to R₈ are independently selected from hydrogen and C₁ to C₆ alkyl, R₅₀ is —(CH₂)ₕNH₂, —CO(CH₂)ₕNH₂, —(CH₂)ₕCONH₂, —NR₅₂R₅₄; A is selected from a single bond, O, C(O), (C═O)O, NR₅₈, CO(CH₂)ₕ, and (CH₂)ₕO, and C₁ to C₄ alkyl; h is 1 to 6; R₅₂ and R₅₄ are each independently selected from hydrogen, alkyl, (CH₂)ₕOH, and (CH₂)ₕCOOH; R₅₈ is selected from hydrogen and alkyl; d is 1 to 3; and X, Y, Z and N (nitrogen) combine to form a cyclic structure where A is bound to any atom in the cyclic structure, further where,
X is selected from C₁ to C₆ alkylene, unsaturated C₁ to C₆ alkylene, direct bond, and mixtures thereof,
Y is selected from C₁ to C₆ alkylene, unsaturated C₁ to C₆ alkylene, direct bond, and mixtures thereof,
Z is selected from 0, C═O, NR₅₆, and N where R₅₆ is selected from hydrogen, alkyl, aryl, and aralkyl.
   The nitrogen containing ring in structure 3′ may comprise one or more saturated bonds, one or more unsaturated bonds, be aromatic or mixtures thereof. The unsaturated bond may be a double bond. Alkylene is generally referred to as linear or branched within the present invention. Examples of the nitrogen containing cyclic group may be without limitation imidazole, N-pyrrolidone, caprolactam, N-morpholine, piperdine, aziridine and triazine.

Further examples of monomeric units of structure 3 are monomeric units of structure (3a) and (3b),

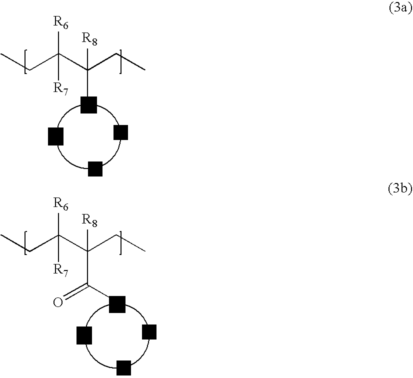

where R₆ to R₈ are independently selected from hydrogen and C₁ to C₆ alkyl, and moiety defined by X, Y, Z are as above in structure 3. The nitrogen containing cyclic moiety of structures 3a and 3b, may comprise one or more saturated bonds in the cyclic structure, one or more unsaturated bonds in the cyclic structure, be an aromatic ring, or mixtures thereof. Examples of the cyclic moiety are imidazole, N-pyrrolidone, caprolactam, N-morpholine, piperdine, aziridine, aziridone, and triazine. Further examples of units of structure (3) include

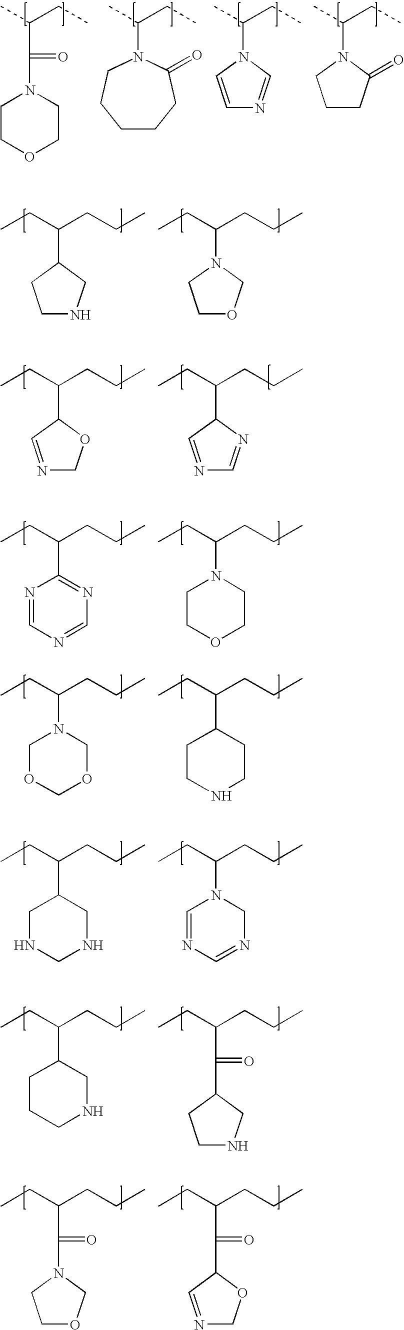

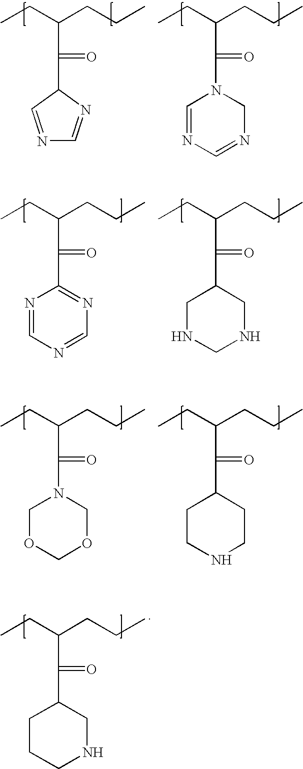

In one embodiment of the polymer, the polymer may comprise at least one monomeric unit of structure (2) as above, optionally a monomeric unit of structure (3) as above, and a third monomeric unit of structure (4),

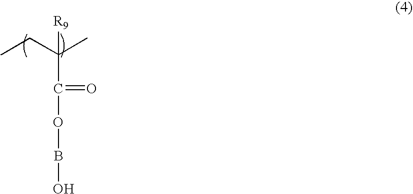

where R₉ is H or C₁ to C₆ alkyl and B is C₁ to C₆ alkylene. B may be an unsubstituted or substituted branched or linear C₁ to C₆ alkylene. The group B may be ethylene, propylene or butylene, and R₉ may be hydrogen or methyl. One example of a monomer which provides the unit of structure 4 is hydroxyethymethacrylate.

The monomer which provides the monomeric unit of structure (2) may be copolymerized with other vinyl monomers, such as exemplified without limitation by those of structure 3 and 4 and also exemplified by N-vinyl pyrrolidone, acrylic acid, vinyl alcohol, methacrylic acid, N-vinylimidizole, acrylamide, allylamine, vinyl triazines, 2-vinyl-4,6-diamino-1,3,5-triazine, diallylamine, vinylamine; N-acryloylmorpholine, piperidinyl methacrylate; and bifunctional monomers such as ethyleneglycoldiacrylate, and ethyleneglycoldimethacrylate. The polymer may comprise a mixture of several monomeric units.

In one embodiment of the polymer, the polymer is free of pendant acrylate groups and/or amide groups. The polymer does not use monomers such as (meth)acrylamide in the synthesis of the present inventive polymer. In one embodiment of the composition, the composition contains 1) the novel polymer comprising structure 2 and is free of any amide groups, such as monomeric units derived from (meth)acrylamide, 2) optionally a surfactant, and 3) water.

In one embodiment, the polymer is polymerized from mixtures of at least one of 2-dimethylaminoethyl methacrylate, and at least one of acryloyl morpholine, N-vinyl caprolactam, and N vinyl pyrrolidone. In another embodiment the copolymers containing the alkylamino group are exemplified by poly(2-dimethylaminoethyl methacrylate-co-vinyl amine), poly(2-dimethylaminoethyl methacrylate-co-allyl amine), poly(2-dimethylaminoethyl methacrylate-co-diallyl amine), poly(2-dimethylaminoethyl methacrylate-co-acryloyl morpholine), poly(2-dimethylaminoethyl methacrylate-co-N-vinyl caprolactam) and poly(2-dimethylaminoethyl methacrylate-co-piperidinyl methacrylate).

The polymer comprising the alkylamino group in one embodiment is free of any aromatic moiety or absorbing chromophore, such as groups containing phenyl moiety. The polymer or the composition does not absorb the radiation used to image the photoresist which is coated beneath the shrink layer. The composition may be free of a photoacid generator such that the composition is not photoimageable.

Another polymer of interest has the formula

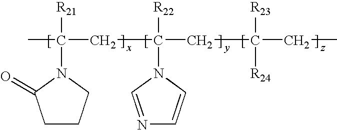

where R₂₁, R₂₂, and R₂₃ each independently represent hydrogen or C₁₋₆ alkyl; R₂₄ is alkyloxycarbonyl group, hydroxyalkyloxycarbonyl group, alkylcarbonyloxy group, or hydroxyalkylcarbonyloxy group; x, y, and z are integers 5 to 1000. Examples of the foregoing groups include —COOCH₃, —COO—(CH₂)ₛ—CH₂—OH, —OCOCH₃, and —OCO—(CH₂)ₜ—CH₂—OH, where s and t are integers 1 to 5.

Examples of the foregoing polymers include poly(N,N-dimethylaminoethylacrylate-co-N-vinylpyrrolidone), poly(N,N-dimethylaminoethylacrylate-co-acryloylmorpholine), poly(acryloylmorpholine-co-N,N-dimethylaminoethylacrylate-co-vinylcaprolactam), poly(acryloylmorpholine-co-N,N-dimethylaminoethylmethacrylate-co-vinylcaprolactam, poly(N,N-dimethylaminoethylmethacrylate-co-vinylimidazole), poly(hydroxyethylmethacrylate-co-N,N-dimethylaminoethylmethacrylate), poly(N-vinylpyrrolidone-co-N-vinylimidazole-co-N-vinylcaprolactam), poly(N-vinylpyrrolidone-co-N-vinylcaprolactam), poly(N-vinylimidazole-co-N-vinylcaprolactam), polyvinylpyrrolidone-co-polyvinylacetate, polyvinylpyrrolidone-co-polyvinylimidazole, and the like.

The water soluble polymers can be made by any polymerization technique. Bulk or solution polymerization may be used. Typically the vinyl monomers are polymerized using a polymerization initiator, such as azo or peroxide initiators. Examples of peroxide initiators are acetyl peroxide, benzoyl peroxide, lauryl peroxide, cumenehydroperoxide, etc. Examples of azo initiators are azobisisobutyronitrile (AIBN), 2,2′-diamidino-2,2′-azodipropane dihydrochloride, 2,2′-azobis[2-(2-imidazolin-2-yl)propane]dihydrochloride, 2,2′-azobis(2-amidino propane)dihydrochloride, 2,2′-azobis[2-(2-imidazolin-2-yl)propane]dihydrochloride and examples of persulfates are such as ammonium persulfates and potassium persulfates. The polymerization can be carried out in the presence of a solvent, examples of which are acetonitrile, methanol, ethanol, isopropanol, 2-butanone and water, preferably for some reactions, isopropanol is used. The reaction can be carried out for a suitable amount of time and at a suitable temperature. The reaction time can range from about 3 hours to about 18 hours. The reaction temperature can range from about 40° C. to about 80° C. The weight average molecular weight of the polymer for the shrink coating material ranges from approximately 3,000 to 100,000, preferably from Mw 5,000 to 100,000, and more preferably from 10,000 to 50,000, but any polymer with the appropriate molecular weight may be used.

For polymers useful in the present composition, the unit of structure 2 may range from about 20 mole % to about 80 mole %; the unit of structure 3 when used in the polymer may range from about 30 mole % to about 80 mole %; the unit of structure 4 when used in the polymer may range from about 20 mole % to about 60 mole %. The copolymer may also comprise the unit of structure 2 in the range from about 20 mole % to about 60 mole % and the unit of structure 3 in the range from about 40 mole % to about 80 mole %. The copolymer may also comprise the unit of structure 2 in the range from about 20 mole % to about 60 mole % and the unit of structure 4 in the range from about 40 mole % to about 60 mole %.

The hardening compound has the formula

R₁₂—(CR₂₀₀—R₃₀₀)ₒ₁-G-(CR₂₀₀R₃₀₀)ₒ₂—R₁₂ (I)

where G is selected from

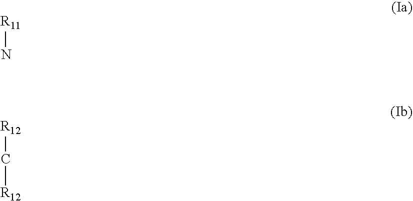

where each of R₂₀₀ and R₃₀₀ are individually selected from hydrogen, hydroxyl, unsubstituted or substituted linear, branched or cyclic alkyl group, unsubstituted or substituted alkenyl group, unsubstituted or substituted aryl group or unsubstituted or substituted aralkyl group; each R₁₂ is a hydrogen atom, —OH, —COOH, —CH₂OH, —NR₁₃R₁₃ₐ, an unsubstituted or substituted linear, branched or cyclic alkyl group, unsubstituted or substituted alkenyl group, unsubstituted or substituted aryl group or unsubstituted or substituted aralkyl group; R₁₁, R₁₃, and R₁₃ₐ are each independently a hydrogen atom or an unsubstituted or substituted linear, branched or cyclic alkyl group; and o1 and o2 represent an integer of 0 to 10.

Methyl, ethyl, n-propyl, isopropyl, n-butyl, isobutyl, s-butyl, t-butyl, n-pentyl, n-hexyl, cyclopropyl, cyclopentyl and cyclohexyl groups are nonlimiting examples for the linear, branched or cyclic alkyl group; vinyl, propylene, butylene, pentylene, hexylene, phenyl, naphthyl, benzyl, phenylethyl groups are nonlimiting examples for alkenyl, aryl and aralkyl groups. Groups that may substitute alkyl, alkenyl, aryl, aralkyl groups include hydroxyl, amino, carbonyl, and the like so long as the substituents do not adversely affect the performance of the hardening compound.

Further, as compounds having at least two amino groups in a molecule, other than those represented by the above formula (I), compounds in which G is N—R₁₁ and R₁₂ is —NR₁₃R₁₃ₐ and two amino groups therefrom jointly make a ring to form a heterocyclic compound including two nitrogen atoms, such as imidazolidine, piperazine, imidazolidinone are exemplified. They are, for example, 1-(hydroxymethyl)-imidazolidinone, 1-(2-hydroxyethyl)-imidazolidinone, 1-(2-hydroxypropyl)-imidazolidinone, 2-(1-piperazinyl)ethanol and 2-(4-amino-1-piperazinyl)ethanol etc.

A further example of the compounds of formula (I) include those having the formula

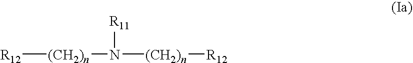

where R₁₁ and R₁₂ are defined above and n is an integer 1 to 8.

As other compounds having at least two amino groups in a molecule, ((aminoacetyl)amino)acetic acid, ((2-aminopropanoyl)amino)acetic acid, N-(aminoacetyl)alanine, (aminoacetylmethylamino)acetic acid, 2-(2-dimethylaminoethylmethylamino)ethanol, 2-(2-(2-hydroxyethyl)amino)ethyl)aminoethanol, (2-(2-amino-2-methylpropyl)amino)-2-methyl-1-propanol, 1,4-bis(2-hydroxyethyl)piperazine, 2-(4-morpholinyl)ethaneamine, and N,N-bis(2-hydroxyethyl)ethylenediamine etc. are exemplified.

Examples of the hardening compound include 2-(2-aminoethylamino)ethanol, 2-(2-aminopropylamino)ethanol, 2-(2-aminobutylamino)ethanol, 2-(2-aminoethylamino)propanol, 2-(2-aminopropylamino)propanol, 2-(2-aminobutylamino)propanol, 2-(2-aminoethylamino)isopropanol, 2-(2-aminopropylamino)isopropanol, 2-(2-aminobutylamino)isopropanol, 2-(2-aminoethylamino)butanol, 2-(2-aminopropylamino)butanol, 2-(2-aminobutylamino)butanol, 2-(2-methylaminoethylamino)ethanol, 2-(2-methylaminopropylamino)ethanol, 2-(2-methylaminobutylamino)ethanol, 2-(2-methylaminoethylamino)propanol, 2-(2-methylaminopropylamino)propanol, 2-(2-methylaminobutylamino)propanol, 2-(2-methylaminoethylamino)isopropanol, 2-(2-methylaminopropylamino)isopropanol, 2-(2-methylaminobutylamino)isopropanol, 2-(2-methylaminoethylamino)butanol, 2-(2-methylaminopropylamino)butanol, 2-(2-methylaminobutylamino)butanol, 2-(2-ethylaminoethylamino)ethanol, 2-(2-ethylaminopropylamino)ethanol, 2-(2-ethylaminobutylamino)ethanol, 2-(2-ethylaminoethylamino)propanol, 2-(2-ethylaminopropylamino)propanol, 2-(2-ethylaminobutylamino)propanol, 2-(2-ethylaminoethylamino)isopropanol, 2-(2-ethylaminopropylamino)isopropanol, 2-(2-ethylaminobutylamino)isopropanol, 2-(2-ethylaminoethylamino)butanol, 2-(2-ethylaminopropylamino)butanol, 2-(2-ethylaminobutylamino)butanol, 2-(2-aminoethylmethylamino)ethanol, 2-(2-methylaminomethylamino)ethanol, 2-(2-aminomethylamino)propanol, 2-(2-aminomethylamino)isopropanol, 2-(2-aminomethylamino)butanol, 2-(2-amino-1,1-dimethylethylamino)ethanol, 2-(2-amino-1,1-dimethylethylamino)propanol, 2-(2-amino-1,1-dimethylethylamino)butanol, 1,3-diamino-2-propanol, 3-(2-aminoethylamino)propanol, N-methyl diethanolamine, N,N′-tetramethyl-1,3-diamino-2-propanol, 2,3-diamino-1-propanol, N-(2-hydroxyethyl)-1,3-diaminopropane, triethylamine, tri-n-propylamine, tri-isopropylamine, tri-n-butylamine, tri-sec-butylamine, tri-isobutylamine, tri-t-butylamine, N,N-bis(2-hydroxyethyl)ethylenediamine, and mixtures thereof.

Surfactants, if necessary, may be added to the shrink composition to enable better film forming properties. Examples of surfactants are cationic compounds, anionic compounds and nonionic polymers. Examples of surfactants are Surfynols® sold by Air Products Corp., which are acetylene alcohols, including their ethoxylates, for example 3-methyl-1-butyn-3-ol, 3-methyl-1-pentyn-3-ol, 3,6-dimethyl-4-octyne-3,6-diol, 2,4,7,9-tetra-methyl-5-decyne-4,7-diol, 3,5-dimethyl-1-hexyn-3-ol, 2,5-dimethyl-3-hexyne-2,5-diol, 2,5-dimethyl-2,5-hexane-diol, and the like. Others can be acetylene glycols, polyethoxylated acetylene alcohols and polyethoxylated acetylene glycols.

The hardening composition can optionally contain a thermal acid generator. The thermal acid generator may be any compound that generates an acid when heated at appropriate temperatures, e.g. at 50 to 250° C. Examples of thermal acid generators are nitrobenzyl tosylates, such as 2-nitrobenzyl tosylate, 2,4-dinitrobenzyl tosylate, 2,6-dinitrobenzyl tosylate, 4-nitrobenzyl tosylate; nitrobenzyl benzenesulfonates such as 2-trifluoromethyl-6-nitrobenzyl4-chlorobenzenesulfonate, 2-trifluoromethyl-6-nitrobenzyl4-nitro benzenesulfonate; phenolic sulfonate esters such as phenyl4-methoxybenzenesulfonate; 2,4,4,6-tetrabromocyclohexadienone, benzoin sulfonates such as benzoin tosylate and benzoin benzenesulfonate; onium sulfonates such as benzylmethylphenylsulfonium trifluoromethanesulfonate, benzyl(4-hydroxyphenyl)methylsulfonium trifluoromethanesulfonate, benzenediazonium trifluoromethanesulfonate, and naphthalenediazonium trifluoromethanesulfonate; sulfonium salts, diazonium salts, halogen-containing compounds, sulfonate compounds, and other alkyl esters of organic sulfonic acids Other thermal acid generators can have a general formula of

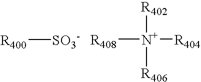

where R₄₀₀, R₄₀₂, R₄₀₄, R₄₀₆, and R₄₀₈ are each unsubstituted or substituted linear, branched, or cyclic alkyl, unsubstituted or substituted linear, branched, or cyclic alkene, unsubstituted or substituted linear, branched, or cyclic alkyne, unsubstituted or substituted aryl, or unsubstituted or substituted aralkyl. Other suitable thermally activated acid generators are described in U.S. Pat. Nos. 5,886,102 and 5,939,236, the contents of which are incorporated herein by reference. The thermal acid generator, when present, is generally added in an amount of about 10 to about 20% based on the polymer weight.

The solvent for the hardening composition is water, organic solvent, or a mixture thereof. Since the solvent will be used in and around semiconductor devices, the water and organic solvent should be free of impurities or metal ions. Such can be removed by treatments well known to those skilled in the art, for example, distillation, ion-exchange, filtration, etc. Examples of the organic solvent include, (C₁-C₈)alcohols such as methyl alcohol, ethyl alcohol, isopropyl alcohol, diols (such as glycols) and triols (such as glycerol); ketones such as acetone, methyl ethyl ketone, 2-heptanone, cyclohexanone; esters such as methyl acetate and ethyl acetate; lactates such as methyl lactate and ethyl lactate, lactones such as gamma-butyrolactone; amides such as N,N-dimethyl acetamide; ethylene glycol monoalkyl ethers such as ethylene glycol monomethyl ether, and ethylene glycol monoethyl ether; ethylene glycol monoalkyl ether acetate such as ethylene glycol monomethyl ether acetate, ethylene glycol monoethyl ether acetate; other solvents such as N-methyl pyrrolidone, propylene glycol monomethyl ether, propylene glycol monoethyl ether, propylene glycol monomethyl ether acetate, propylene glycol monoethyl ether acetate. The solvent may be added to the composition at up to about 30 weight % or up to 20 weight % of the total composition. The organic solvent can be selected such that it is different from the organic solvents that are used in the first photoresist. When a mixture of water and organic solvent is used, the organic solvent is not particularly limited as long as it can be soluble in water in a concentration of 0.1 wt % or more.

The present invention relates to a process for imaging fine patterns on a microelectronic device using double imagewise patterning of two photoresist layers. The process comprises patterning of a first photoresist layer followed by a second imagewise (using a mask or reticle) photoresist patterning step which forms a pattern interdigitated to the first pattern. Interdigitated refers to an alternating pattern of the second pattern placed between the first pattern. The double patterning step allows for an increase in pattern density as compared to a single patterning step. The inventive process comprises, a) forming a layer of first photoresist on a substrate from a first photoresist composition; b) imagewise exposing the first photoresist; c) developing the first photoresist to form a first photoresist pattern; d) treating the first photoresist pattern with a hardening composition comprising a polymer, a hardening compound, optionally a surfactant, optionally a thermal acid generator, and a solvent selected from water, organic solvent, or a mixture thereof, thereby forming a hardened first photoresist pattern; e) forming a second photoresist layer on the region of the substrate including the hardened first photoresist pattern from a second photoresist composition; f) imagewise exposing the second photoresist; and, g) developing the second photoresist pattern between the first photoresist pattern, thereby forming a double photoresist pattern. The second pattern is interdigitated to the first pattern, that is, an alternating first and second pattern is formed.

The treating step comprises the steps of (i) coating the first photoresist pattern with the hardening composition, (ii) soft baking the coated first photoresist pattern of (i), (iii) developing the baked coated first photoresist pattern of (ii) with water or an aqueous alkaline solution to remove the hardening composition, and (iv) optionally hard baking the developed first photoresist pattern of (iii).

The soft bake temperature of the hardening composition in step (ii) can range from about 80° C. to about 180° C. Developing the hardening composition can be done with water or typical aqueous alkaline developers, for example, tetramethyl ammonium hydroxide, for about 30 seconds to about 120 seconds using typical applications (puddle, spray, dip, etc). After developing the hardened composition, the developed first photoresist pattern of step (iii) is then subjected to an optional hard bake at a temperature from about 80° C. to about 230° C., and further from about 140° C. to about 230° C. After the hard bake, if performed, the wafer is then ready for coating with the second photoresist film and formation of the double patterned features.

After the appropriate amount of hardening of the first photoresist pattern and prior to coating with the second photoresist, the first photoresist pattern may optionally be treated with a cleaning solution. Examples of cleaning solutions can be edge bead removers for photoresists such as AZ® ArF Thinner or AZ® ArF MP Thinner available commercially, or any of the photoresist solvent(s).

The first photoresist pattern is then coated to form a second layer of the second photoresist from a second photoresist composition. The second layer is thinner than the thickness of the first photoresist layer to reduce topography effects. The second photoresist comprises a polymer, a photoacid generator and a solvent. The second photoresist may be the same or different than the first photoresist. The second photoresist may be chosen from any known photoresists, such as those described herein. The second photoresist is imagewise exposed and developed as described previously, and similar to the first photoresist. An edge bead remover may be used on the second photoresist layer after forming the coating. The second photoresist pattern now is defined between the first photoresist pattern and allows for the patterning of smaller and more features in the device than a single layer imaging process. The density of the photoresist pattern is increased.

The process of coating and imaging single layers of photoresists is well known to those skilled in the art and is optimized for the specific type of photoresist used. The image transfer through to the substrate from the imaged photoresist and through the antireflective coatings is carried out by dry etching in a similar manner used for etching through a single layer photoresist coating. The patterned substrate can then be dry etched with an etching gas or mixture of gases, in a suitable etch chamber to remove the exposed portions of the antireflective film, with the remaining photoresist acting as an etch mask. Various gases are known in the art for etching organic antireflective coatings, such as O₂, Cl₂, F₂ and CF₄.

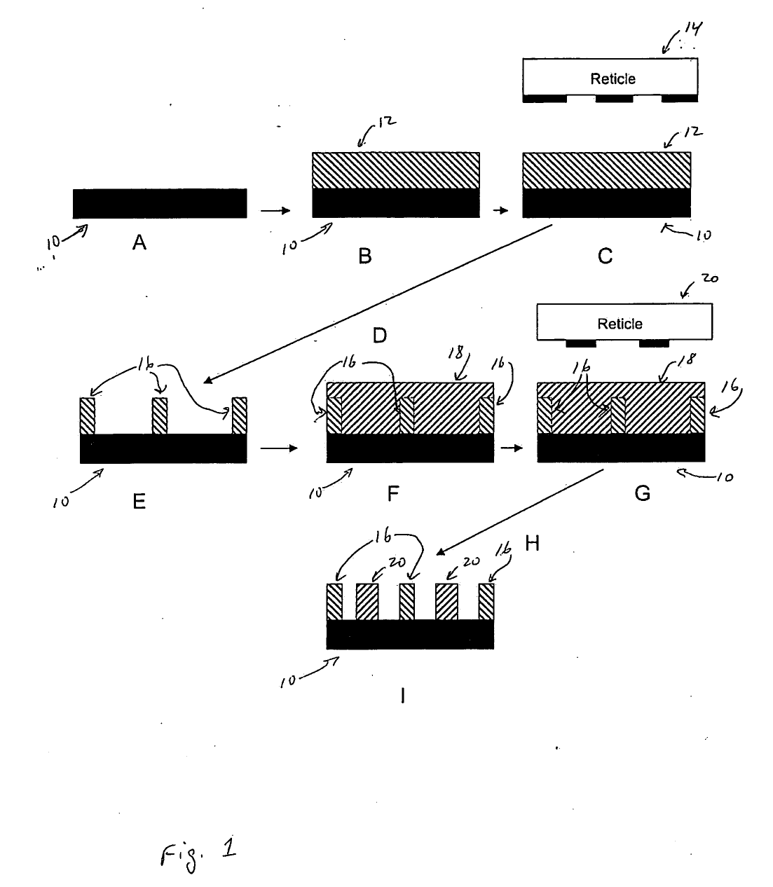

In FIG. 1, a substrate 10, which has been coated with a bottom antireflective coating (BARC) is provided in step A. In step B, the substrate 10 is coated with a first photoresist 12 and the coated substrate is soft baked. The substrate 10 coated with photoresist 12 is then image-wise exposed using reticle 14 in step C. After imagewise exposure in step C, the substrate 10 coated with photoresist 12 is then post-exposure baked and developed in step D to then provide a substrate 10 with features 16 from the first photoresist in step E.

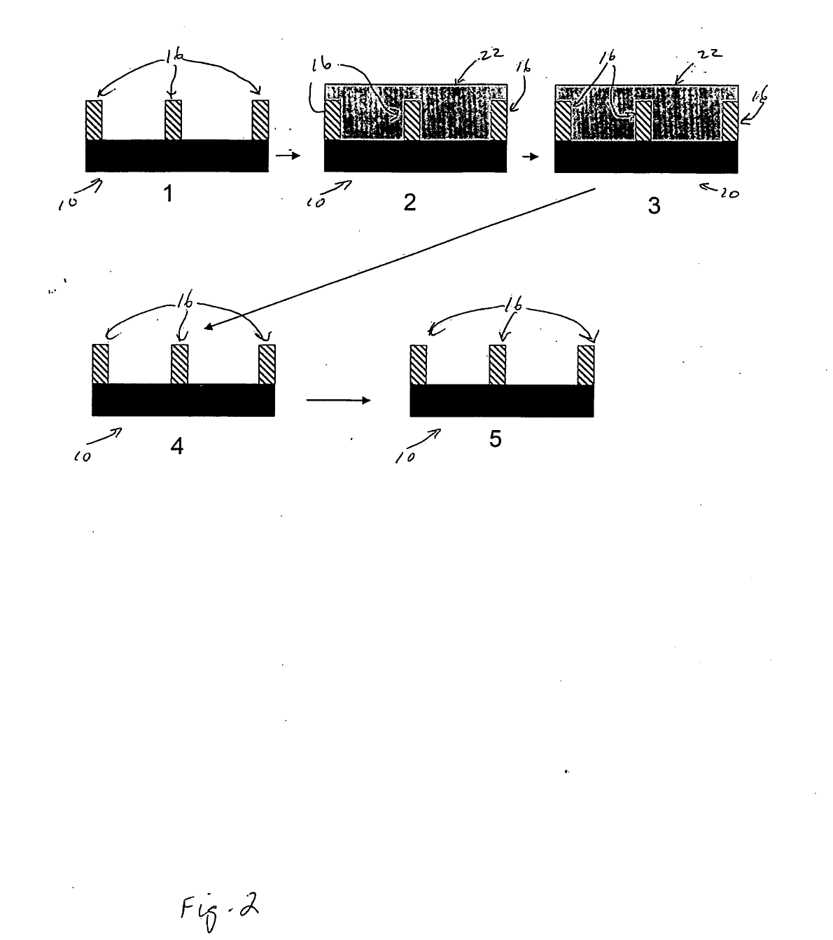

Between step E and step F is the treating step with the hardening composition. The treating step is more fully described in the discussion regarding FIG. 2 below. In step F, a second photoresist 18 is coated over substrate 10 which now has features 16 resulting from the first exposure and development from steps C and D. There is no need to apply a BARC since the BARC from the first exposure remains. The substrate 10 having features 16 and coated with second photoresist 18 is then soft baked. The substrate 10 having features 16 and coated with second photoresist 18 is then image-wise exposed with reticle 20, which has the same features and pitch as reticle 14. In some processes, the reticles 14 and 20 will have different features.

After the imagewise exposure in step G, the substrate 10 having features 16 and coated with photoresist 18 is then post-exposure baked and developed in step H to then provide a substrate 10 with features 16 from the first photoresist and features 20 from second photoresist 18 in step I.

FIG. 2 shows the treating step with the hardening composition. In step 1 is substrate 10 with features 16 formed in step E of FIG. 1. Substrate 10 with features 16 is then coated with hardening composition 22 in step 2. In step 3, the substrate 10 with features 16 and coated with hardening composition 22 is then soft baked, typically at a temperature from about 80° C. to about 180° C. Going from step 3 to step 4, the substrate 10 with features 16 and coated with hardening composition 22 that was soft baked in step 3 is then developed using water or an aqueous alkaline developer, for example, tetramethyl ammonium hydroxide. Going from step 4 to step 5 is optional; the developed substrate 10 from step 4 is then optionally hard baked at a temperature of from about 80° C. to about 230° C., and further from about 140° C. to about 230° C., in step 5. The resulting substrate 10 with features 16 in step 5 is then ready for further treated in step F as discussed in FIG. 1 above.

Unless otherwise indicated, all numbers expressing quantities of ingredients, properties such as molecular weight, reaction conditions, and so forth used in the specification and claims are to be understood as being modified in all instances by the term “about.” Each of the documents referred to above are incorporated herein by reference in its entirety, for all purposes. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### EXAMPLES

### Example 1

### Synthesis of Poly(N,N-dimethylaminoethylacrylate-co-N-vinylpyrrolidone)

A mixture of N,N-dimethylaminoethylacrylate (25.70 g, 0.1795 mol), N-vinylpyrrolidone (19.95 g, 0.1795 mol), 6.85 g of initiator, azobisisobutyronitrile, and 97.50 g of acetonitrile were added to a 500 ml round bottom flask equipped with water condenser and nitrogen inlet. The initiator concentration was 15 wt % relative to the total weight of the monomers. Other solvents such as isopropyl alcohol (IPA), 2-butanone and methanol can also be used instead of acetonitrile. Nitrogen gas was purged into the solution for 30 minutes at room temperature with stirring. After the nitrogen purge, the reaction solution was heated to 65° C. The polymerization reaction was carried out for 6 hours. After the completion of polymerization, the polymer solution was cooled to 30° C. and concentrated using rotary evaporator. The concentrated solution was precipitated in diethyl ether. Other solvents such as diisopropyl ether and tertbutylmethyl ether may also be used. The amount of precipitating solvent used was 7 times that of the initial volume of reaction. The final copolymer was vacuum dried at 40° C. and the yield was 70%. The weight average molecular weight of the polymer was 24,832 (Mw) and polydispersity was 4.0.

Using similar procedures, other examples of polymers can be made and include poly(N,N-dimethylaminoethylacrylate-co-acryloylmorpholine), poly(acryloylmorpholine-co-N,N-dimethylaminoethylacrylate-co-vinylcaprolactam), poly(acryloylmorpholine-co-N,N-dimethylaminoethylmethacrylate-co-vinylcaprolactam, poly(N,N-dimethylaminoethylmethacrylate-co-vinylimidazole), poly(hydroxyethylmethacrylate-co-N,N-dimethylaminoethylmethacrylate), poly(N-vinylpyrrolidone-co-N-vinylimidazole-co-N-vinylcaprolactam), poly(N-vinylpyrrolidone-co-N-vinylcaprolactam), poly(N-vinylimidazole-co-N-vinylcaprolactam), poly(vinylpyrrolidone-co-polyvinylacetate), poly(vinylpyrrolidone-co-polyvinylimidazole), poly(N-N,dimethylaminoethylacrylate-co-acryloylmorpholine), and the like.

### Example 2

### Hardening Composition

A mixture of 2.9630 g of poly(N-N,dimethylaminoethylacrylate-co-N-vinylpyrrolidone (polymer from Example 1), 0.0370 g of surfactant SF-485 (an acetylenic based non-ionic surfactant available from Takemoto Oil & Fat Co.), and 1.000 g of 2-(2-aminoethylamino)ethanol were dissolved in 96.000 g of deionized (DI) water to prepare a hardening composition. The solution was filtered using 0.2 μm filter. The total solid content in the formulation was 4%.

Film thicknesses measurements were performed on a Nanospec 8000 using Cauchy's material-dependent constants derived on a J. A. Woollam® VUV VASE® Spectroscopic Ellipsometer. Photoresist on bottom antireflective coatings were modeled to fit the photoresist film thickness only.

CD-SEM measurements were done on either an Applied Materials SEM Vision or NanoSEM. Cross-sectional SEM images were obtained on a Hitachi 4700.

Lithography exposures were performed on a Nikon NSR-306D (NA: 0.85) interfaced to a Tokyo Electron Clean Track ACT 8 (for 8 inch wafers). The wafers were coated with AZ® ArF-1C5D (a bottom antireflective coating available from AZ Electronic Materials USA Corp., Somerville, N.J., USA) and baked at 200° C./60 sec to achieve 37 nm film thickness. Commercial AZ® AX2110P (available from AZ Electronic Materials USA Corp., Somerville, N.J., USA) photoresist was diluted with AZ® ArF MP Thinner (80:20 methyl-2-hydroxyisobutyrate:PGMEA) so that 90 nm film could be achieved with a coater spin rate of 1500 rpm. A 6% halftone phase shift mask was used for exposure. The ADI pattern is 55 nm line (pitch 220 nm) for the first exposure. For the second exposure described below, the pattern is 55 nm line (pitch 220 nm). The photoresist was soft baked at 100° C./60 s and post-exposure baked (PEB) at 110° C./60 s. After PEB, the wafers were developed for 60 seconds with a surfactant-free developer, AZ® 300MIF (available from AZ Electronic Materials USA Corps, Somerville, N.J., USA), containing 2.38% tetramethyl ammonium hydroxide (TMAH).

Hardening of the first photoresist exposure was done by spin-coating the composition from Example 2 on top of the exposed first photoresist layer at 1500 rpm to form a film thickness of 80 nm. The hardening composition of Example 2 was then soft baked at 110° C./60 s. After soft baking, the wafers were developed for 60 seconds with a surfactant-free developer, AZ® 300MIF. The developed wafers were then hard baked at 160° C./120 s.

The hardened first exposed photoresist layer was then subjected to a second exposure using the same photoresist composition and the same processing conditions as the first photoresist exposure above except that the film thickness for the second layer of photoresist was 80 nm. No bottom antireflective coating (BARC) was necessary since the BARC from the 1^{st} exposure remains. A 6% halftone phase shift mask was used for exposure. The same mask as in the first exposure was used with the ADI pattern being 55 nm line (pitch 110 nm).

CD-SEM showed that a dense pattern was achieved. Post second photoresist image kept the same CD (critical dimension) as the CD after the first exposure and development.

### Example 3

### Hardening Composition

A mixture of 2.9630 g of poly(N-N,dimethylaminoethylacrylate-co-N-vinylpyrrolidone) (polymer from Example 1 but with monomer ratio of X:Y), 0.0370 g of surfactant SF-485 (an acetylenic based non-ionic surfactant available from Takemoto Oil & Fat Co.), and 1.000 g of 2-(2-aminoethylamino)ethanol were dissolved in 96.000 g of deionized (DI) water to prepare a hardening composition. The solution was filtered using 0.2 μm filter. The total solid content in the formulation was 4%.

### Example 4

### Hardening Composition

A mixture of 2.9630 g of poly(N-vinylpyrrolidone-co-polyvinylimidazole), 0.0370 g of surfactant SF-485 (an acetylenic based non-ionic surfactant available from Takemoto Oil & Fat Co.), and 1.000 g of 2-(2-aminoethylamino)ethanol were dissolved in 96.000 g of deionized (DI) water to prepare a hardening composition. The solution was filtered using 0.2 μm filter. The total solid content in the formulation was 4%.

### Example 5

### Hardening Composition

A mixture of 2.9630 g of poly(allylamine), 0.0370 g of surfactant SF-485 (an acetylenic based non-ionic surfactant available from Takemoto Oil & Fat Co.), and 1.000 g of 2-(2-aminoethylamino)ethanol were dissolved in 96.000 g of deionized (DI) water to prepare a hardening composition. The solution was filtered using 0.2 μm filter. The total solid content in the formulation was 4%.

### Example 6

### Hardening Composition

A mixture of 2.9630 g of poly(N-N,dimethylaminoethylacrylate-co-acryloylmorpholine), 0.0370 g of surfactant SF-485 (an acetylenic based non-ionic surfactant available from Takemoto Oil & Fat Co.), and 1.000 g of 2-(2-aminoethylamino)ethanol were dissolved in 96.000 g of deionized (DI) water to prepare a hardening composition. The solution was filtered using 0.2 μm filter. The total solid content in the formulation was 4%.

### Example 7

### Hardening Composition

A mixture of 2.9630 g of poly(N-vinylpyrrolidone-co-vinylcaprolactam), 0.0370 g of surfactant SF-485 (an acetylenic based non-ionic surfactant available from Takemoto Oil & Fat Co.), and 1.000 g of 2-(2-aminoethylamino)ethanol were dissolved in 96.000 g of deionized (DI) water to prepare a hardening composition. The solution was filtered using 0.2 μm filter. The total solid content in the formulation was 4%.

Lithography exposures of Examples 3 to 7 were performed in the same manner and were evaluated as that described in Example 2. In all instances, CD-SEM showed that a dense pattern was achieved. Post second photoresist image kept relatively the same CD (critical dimension) as the CD after the first exposure and development.

### Example 8

### Hardening Composition

A mixture of 2.9630 g of poly(N-N,dimethylaminoethylacrylate-co-N-vinylpyrrolidone) (polymer from Example 1), 0.0370 g of surfactant SF-485 (an acetylenic based non-ionic surfactant available from Takemoto Oil & Fat Co.), and 1.000 g of 1,3-diamino-2-propanol were dissolved in 96.000 g of deionized (DI) water to prepare a hardening composition. The solution was filtered using 0.2 μm filter. The total solid content in the formulation was 4%.

### Example 9

### Hardening Composition

A mixture of 2.9630 g of poly(N-N,dimethylaminoethylacrylate-co-N-vinylpyrrolidone) (polymer from Example 1 but with monomer ratio of X:Y), 0.0370 g of surfactant SF-485 (an acetylenic based non-ionic surfactant available from Takemoto Oil & Fat Co.), and 1.000 g of 1,3-diamino-2-propanol were dissolved in 96.000 g of deionized (DI) water to prepare a hardening composition. The solution was filtered using 0.2 μm filter. The total solid content in the formulation was 4%.

### Example 10

### Hardening Composition

A mixture of 2.9630 g of poly(N-vinylpyrrolidone-co-polyvinylimidazole), 0.0370 g of surfactant SF-485 (an acetylenic based non-ionic surfactant available from Takemoto Oil & Fat Co.), and 1.000 g of 1,3-diamino-2-propanol were dissolved in 96.000 g of deionized (DI) water to prepare a hardening composition. The solution was filtered using 0.2 μm filter. The total solid content in the formulation was 4%.

### Example 11

### Hardening Composition

A mixture of 2.9630 g of poly(allylamine), 0.0370 g of surfactant SF-485 (an acetylenic based non-ionic surfactant available from Takemoto Oil & Fat Co.), and 1.000 g of 1,3-diamino-2-propanol were dissolved in 96.000 g of deionized (DI) water to prepare a hardening composition. The solution was filtered using 0.2 μm filter. The total solid content in the formulation was 4%.

### Example 12

### Hardening Composition

A mixture of 2.9630 g of poly(N-N,dimethylaminoethylacrylate-co-acryloylmorpholine), 0.0370 g of surfactant SF-485 (an acetylenic based non-ionic surfactant available from Takemoto Oil & Fat Co.), and 1.000 g of 1,3-diamino-2-propanol were dissolved in 96.000 g of deionized (DI) water to prepare a hardening composition. The solution was filtered using 0.2 μm filter. The total solid content in the formulation was 4%.

### Example 13

### Hardening Composition

A mixture of 2.9630 g of poly(N-vinylpyrrolidone-co-vinylcaprolactam), 0.0370 g of surfactant SF-485 (an acetylenic based non-ionic surfactant available from Takemoto Oil & Fat Co.), and 1.000 g of 1,3-diamino-2-propanol were dissolved in 96.000 g of deionized (DI) water to prepare a hardening composition. The solution was filtered using 0.2 μm filter. The total solid content in the formulation was 4%.

Lithography exposures of Examples 8 to 13 were performed in the same manner and were evaluated as that described in Example 2. In all instances, CD-SEM showed that a dense pattern was achieved. Post second photoresist image kept the same CD (critical dimension) as the CD after the first exposure and development.

1. A process for forming a double photoresist pattern on a device, comprising;
a) forming a layer of first photoresist on a substrate from a first photoresist composition;
b) imagewise exposing the first photoresist;
c) developing the first photoresist to form a first photoresist pattern;
d) treating the first photoresist pattern with a hardening composition comprising a polymer, a hardening compound, optionally a surfactant, optionally a thermal acid generator, and a solvent selected from water, organic solvent, or a mixture thereof, thereby forming a hardened first photoresist pattern;
e) forming a second photoresist layer on the region of the substrate including the hardened first photoresist pattern from a second photoresist composition;
f) imagewise exposing the second photoresist; and,
g) developing the imagewise exposed second photoresist to form a second photoresist pattern between the first photoresist pattern, thereby providing a double photoresist pattern.

2. The process of claim 1, where the hardening compound has the formula
R₁₂—(CR₂₀₀R₃₀₀)ₒ₁-G-(CR₂₀₀R₃₀₀)ₒ₂—R₁₂ (I)
where G is selected from 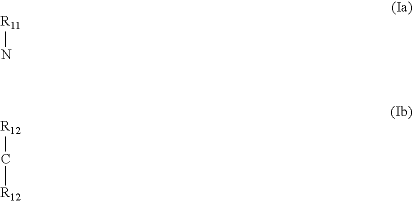
where each of R₂₀₀ and R₃₀₀ are individually selected from hydrogen, hydroxyl, unsubstituted or substituted linear, branched or cyclic alkyl group, unsubstituted or substituted alkenyl group, unsubstituted or substituted aryl group or unsubstituted or substituted aralkyl group; each R₁₂ is a hydrogen atom, —OH, —COOH, —CH₂OH, —NR₁₃R₁₃ₐ, an unsubstituted or substituted linear, branched or cyclic alkyl group, unsubstituted or substituted alkenyl group, unsubstituted or substituted aryl group or unsubstituted or substituted aralkyl group; R₁₁, R₁₃, and R₁₃ₐ are each independently a hydrogen atom or an unsubstituted or substituted linear, branched or cyclic alkyl group; and o1 and o2 represent an integer of 0 to 10.

3. The process of claim 1, where the hardening compound has the formula 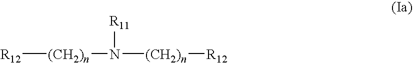
where R₁₂ is a hydrogen atom, —OH, —COOH, —CH₂OH, —NR₁₃R₁₃ₐ, an unsubstituted or substituted linear, branched or cyclic alkyl group, unsubstituted or substituted alkenyl group, unsubstituted or substituted aryl group or unsubstituted or substituted aralkyl group; R₁₁, R₁₃, and R₁₃ₐ are each independently a hydrogen atom or an unsubstituted or substituted linear, branched or cyclic alkyl group; and n is an integer 1 to 8.

4. The process of claim 1, where the hardening compound is selected from 2-(2-aminoethylamino)ethanol, 2-(2-aminopropylamino)ethanol, 2-(2-aminobutylamino)ethanol, 2-(2-aminoethylamino)propanol, 2-(2-aminopropylamino)propanol, 2-(2-aminobutylamino)propanol, 2-(2-aminoethylamino)isopropanol, 2-(2-aminopropylamino)isopropanol, 2-(2-aminobutylamino)isopropanol, 2-(2-aminoethylamino)butanol, 2-(2-aminopropylamino)butanol, 2-(2-aminobutylamino)butanol, 2-(2-methylaminoethylamino)ethanol, 2-(2-methylaminopropylamino)ethanol, 2-(2-methylaminobutylamino)ethanol, 2-(2-methylaminoethylamino)propanol, 2-(2-methylaminopropylamino)propanol, 2-(2-methylaminobutylamino)propanol, 2-(2-methylaminoethylamino)isopropanol, 2-(2-methylaminopropylamino)isopropanol, 2-(2-methylaminobutylamino)isopropanol, 2-(2-methylaminoethylamino)butanol, 2-(2-methylaminopropylamino)butanol, 2-(2-methylaminobutylamino)butanol, 2-(2-ethylaminoethylamino)ethanol, 2-(2-ethylaminopropylamino)ethanol, 2-(2-ethylaminobutylamino)ethanol, 2-(2-ethylaminoethylamino)propanol, 2-(2-ethylaminopropylamino)propanol, 2-(2-ethylaminobutylamino)propanol, 2-(2-ethylaminoethylamino)isopropanol, 2-(2-ethylaminopropylamino)isopropanol, 2-(2-ethylaminobutylamino)isopropanol, 2-(2-ethylaminoethylamino)butanol, 2-(2-ethylaminopropylamino)butanol, 2-(2-ethylaminobutylamino)butanol, 2-(2-aminoethylmethylamino)ethanol, 2-(2-methylaminomethylamino)ethanol, 2-(2-aminomethylamino)propanol, 2-(2-aminomethylamino)isopropanol, 2-(2-aminomethylamino)butanol, 2-(2-amino-1,1-dimethylethylamino)ethanol, 2-(2-amino-1,1-dimethylethylamino)propanol, 2-(2-amino-1,1-dimethylethylamino)butanol, 1,3-diamino-2-propanol, 3-(2-aminoethylamino)propanol, N-methyl diethanolamine, N,N′-tetramethyl-1,3-diamino-2-propanol, 2,3-diamino-1-propanol, N-(2-hydroxyethyl)-1,3-diaminopropane, triethylamine, tri-n-propylamine, tri-isopropylamine, tri-n-butylamine, tri-sec-butylamine, tri-isobutylamine, tri-t-butylamine, N,N-bis(2-hydroxyethyl)ethylenediamine, and mixtures thereof.

5. The process of claim 1, where the hardening composition contains a thermal acid generator.

6. The process of claim 1, where the treating step comprises the steps of (i) coating the first photoresist pattern with the hardening composition, (ii) soft baking the coated first photoresist pattern of (i), (iii) developing the baked coated first photoresist pattern of (ii) with water or an aqueous alkaline solution to remove the hardening composition, and (iv) optionally hard baking the developed first photoresist pattern of (iii).

7. The process of claim 6, where the treating step further comprises the step of (iv) hard baking the developed first photoresist pattern of (iii).

8. The process of claim 6, where the soft baking step (ii) is in the range of about 80° C. to about 180° C.

9. The process of claim 7, where the hard baking step (iv) is in the range of about 80° C. to about 230° C.

10. The process of claim 1, where the first photoresist composition and the second photoresist composition are the same.

11. The process of claim 1, where after the treating step, the first photoresist is insoluble in solvent of the second photoresist composition.

12. The process of claim 1, where the imagewise exposure is selected from 13.5 nm (EUV), 157 nm, 193 nm, 248 nm, 365 nm, and 436 nm.

13. The process of claim 1, where the developing is with an aqueous alkaline developer.

14. A composition comprising a polymer, a hardening compound having the formula
R₁₂—(CR₂₀₀R₃₀₀)ₒ₁-G-(CR₂₀₀R₃₀₀)ₒ₂—R₁₂ (I)
where G is selected from 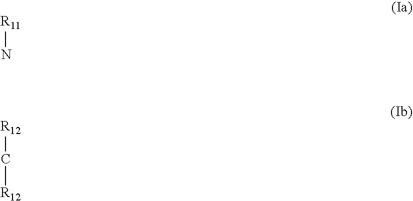
where each of R₂₀₀ and R₃₀₀ are individually selected from hydrogen, hydroxyl, unsubstituted or substituted linear, branched or cyclic alkyl group, unsubstituted or substituted alkenyl group, unsubstituted or substituted aryl group or unsubstituted or substituted aralkyl group; each R₁₂ is a hydrogen atom, —OH, —COOH, —CH₂OH, —NR₁₃R₁₃ₐ, an unsubstituted or substituted linear, branched or cyclic alkyl group, unsubstituted or substituted alkenyl group, unsubstituted or substituted aryl group or unsubstituted or substituted aralkyl group; R₁₁, R₁₃, and R₁₃ₐ are each independently a hydrogen atom or an unsubstituted or substituted linear, branched or cyclic alkyl group; and o1 and o2 represent an integer of 0 to 10; optionally a surfactant, optionally a thermal acid generator, and a solvent selected from water, organic solvent, or a mixture thereof.

15. The composition of claim 14, where the hardening compound has the formula 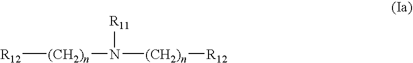
where R₁₂ is a hydrogen atom, —OH, —COOH, —CH₂OH, —NR₁₃R₁₃ₐ, an unsubstituted or substituted linear, branched or cyclic alkyl group, unsubstituted or substituted alkenyl group, unsubstituted or substituted aryl group, or unsubstituted or substituted aralkyl group; R₁₁, R₁₃, and R₁₃ₐ are each independently a hydrogen atom or an unsubstituted or substituted linear, branched or cyclic alkyl group; and n is an integer 1 to 8.

16. A coated substrate comprising: a substrate having thereon: a double photoresist pattern comprising a first photoresist pattern and a second photoresist pattern formed by the process of claim 1.

17. The coated substrate of claim 16 where the treating step comprises the steps of (i) coating the first photoresist pattern with the hardening composition, (ii) soft baking the coated first photoresist pattern of (i), (iii) developing the baked coated first photoresist pattern of (ii) with water or an aqueous alkaline solution to remove the hardening composition, and (iv) optionally hard baking the developed first photoresist pattern of (iii).

18. The coated substrate of claim 17, where the treating step further comprises the step of (iv) hard baking the developed first photoresist pattern of (iii).
